(19) United States
(12) Patent Application Publication
(10) Pub. No.: US 2017/0120766 A1
(43) Pub. Date: May 4, 2017

(54) Apparatus And Method For Regulating A State Of Charge Of An Electrical Energy Store

(71) Applicant: Continental Automotive GmbH, Hannover (DE)

(72) Inventors: Tobias Huber, Sinzing (DE); Friedrich Graf, Sinzing (DE)

(73) Assignee: Continental Automotive GmbH, Hannover (DE)

(21) Appl. No.: 15/322,108

(22) PCT Filed: Jun. 19, 2015
(86) PCT No.: PCT/EP2015/063801

§ 371 Date: Dec. 24, 2016

(30) Foreign Application Priority Data
Jun. 27, 2014 (DE) 10 2014 212 451.4

(51) Int. Cl. B60L 11/18; G01R 31/36; H02J 7/00; H01M 10/48; H01M 10/42

(52) U.S. Cl. CPC B60L 11/1861; H01M 10/48; H01M 10/425; H01M 10/486; H02J 7/007; B60L 11/1857; G01R 31/3662; G01R 31/3679; G01R 31/3651; H01M 2010/4271; H01M 2220/20; B60Y 2200/92

(57) ABSTRACT

The present disclosure relates to energy stores. The teachings thereof may be embodied in an apparatus and a method for regulating a state of charge of an electrical energy store. Embodiments may include an apparatus for regulating a state of charge of an electrical energy store, comprising: an acquisition device acquiring operating data related to the electrical energy store; a computer device determining a forecast state of health of the electrical energy store based at least in part on the acquired operating data; and a control device imposing a limit of power consumption and/or a power output of the electrical energy store, or cancelling such a limit, on the basis of a comparison of the determined forecast state of health of the electrical energy store with a value corridor of stored state of health profiles.

### TECHNICAL FIELD

The present invention relates to an apparatus and a method for regulating a state of charge of an electrical energy store.

### TECHNICAL BACKGROUND

Battery management systems and battery modules and also battery systems and hybrid electric motor vehicles are generally known. By way of example, battery management systems are used for monitoring and regulating individual battery cells or battery modules of a battery.

The batteries can provide for example drive energy for at least partly or completely electrically drivable motor vehicles or operating energy for stationary installations, such as wind power installations, for instance.

DE 10 2012 214 091 A1 describes a battery management system, a battery module, a battery system and a corresponding motor vehicle.

### DISCLOSURE OF THE INVENTION

It is an object of the present invention to provide an improved battery management system for an electrical energy store.

This object is achieved by means of the subjects of the independent patent claims. Embodiments and developments can be gathered from the dependent claims, the description and the figures.

A first aspect of the present invention relates to an apparatus for regulating a state of charge of an electrical energy store, wherein the apparatus comprises: an acquisition device designed to acquire operating data of the electrical energy store; a computer device designed to determine a state of health of the electrical energy store with the aid of the acquired operating data (and, if appropriate, also with the aid of stored state of health profiles); and a control device designed to limit a power consumption or a power output of the electrical energy store on the basis of a comparison of the determined state of health of the electrical energy store with a value corridor of stored state of health profiles. The value corridor can comprise an upper limit and a lower limit of the state of health (SOH), wherein the limits change depending on time or depending on the number of load cycles. As a result, the lifetime is kept within predefined limits, wherein, in order to manipulate the lifetime and/or the profile of the state of health, the power consumption and/or output are/is limited, temporarily limited and/or such a limitation is partly or completely cancelled at least temporarily. The introduction of the limitation and the cancellation thereof have a direct influence on the ageing profile, as a result of which this profile is controlled or manipulated. The introduction of the limitation and the complete or partial cancellation thereof can be repeated in order to maintain the profile of the state of health within the value corridor or below the upper limit and above the lower limit.

Furthermore, for example, an influencing of the number of load cycles of the electrical energy store is provided, in so far as this degree of freedom is possible.

According to a further aspect of the invention, a method for regulating a state of charge of an electrical energy store is provided, wherein the method comprises the following method steps: acquiring operating data of the electrical energy store by means of an acquisition device; determining a state of health of the electrical energy store with the aid of the acquired operating data and with the aid of stored state of health profiles by means of a computer device; and limiting a power consumption and/or a power output of the electrical energy store on the basis of a comparison of the determined state of health of the electrical energy store with a value corridor of the stored state of health profiles by means of a control device.

To put it another way, the present invention advantageously makes it possible to calculate a life state, the so-called state of health (SOH), of the battery of the vehicle and to intervene in the battery management system, i.e. in the monitoring and regulation of the rechargeable battery system, on the basis of the calculation.

As a result, an ageing profile that lies within a predetermined or predefinable ageing profile corridor can advantageously be striven for. This advantageously makes it possible to avoid high-load ranges, particularly at low temperatures, for instance temperatures below 5° C. or below −10° C.

The present invention advantageously makes it possible to limit a power consumption and/or a power output of the electrical energy store, and thus, to put it another way, to limit the electrical system power and/or number of cycles of the electrical energy store.

The present invention advantageously makes it possible to provide an improved battery management system for an electrical energy store which provides predictive lifetime or running time management. A limitation of ageing wear is achieved by avoiding high and peak loadings.

The stored state of health profiles can comprise forecast state of health profiles or other state of health profiles obtained by simulation or calculations.

In particular, states of health (or only one state of health) are forecast for a future time (calendric lifetime) or for a future number of cycles (cyclic lifetime), in particular with the aid of the operating data already acquired. The forecast is based on the profile of acquired operating data, for instance the number or rate of peak loadings (i.e. powers whose absolute value exceeds a predefined limit), duration of peak loadings, duration and/or profile of loading profiles, and if appropriate the temperature and/or the state of charge and/or the terminal voltage which the energy store had during the loading. Loading denotes a power flow (i.e. power consumption or power output). In addition, the forecast can be driver-related, such that in the forecast it is also registered which driver drove the vehicle during the acquisition of the operating data or what type of driver (for instance in accordance with a classification such as: sporty/moderate/economical) drove the vehicle during the acquisition of the operating data.

The computer device is designed for these forecasts. The forecast can be performed by extrapolation, for instance, or by learning systems such as neural networks or the like. The forecast can be carried out with the aid of empirically determined data (in particular energy store-specifically).

The forecast states of health (or only one forecast state of health) are compared with the value corridor in order to intervene in the power consumption or output in the event of the value corridor being left, as described. The power consumption and/or output are/is limited (or the limitation is cancelled) if the forecast state of health lies outside the value corridor, in order to prevent the forecast state of health from actually being reached. Instead, this prior adaption of the power consumption and output is intended to improve the actual ageing profile relative to the originally forecast ageing profile, such that the ageing remains as much as possible within the value corridor and therein as near as possible to an optimum line of the value corridor (for example the mean values that define the value corridor). Operating data are then furthermore acquired and a further forecast is performed in order then, if appropriate, to limit the power consumption or output or to cancel this limitation. As a result, the degree of impairment can be modified in advance of the actual ageing profile. An intervention in the ageing characteristic can already be made before considerable ageing.

The term “state of health” (SOH) is defined as the quotient of the maximum capacity that can be drawn and the rated capacity of an electrical energy store and thus describes the irreversible loss of capacity or the ageing of a cell. An unused cell has an SOH of 100%, for example. In the automotive industry, a rechargeable battery or an electrical energy store having an SOH of 80% or lower is deemed to be no longer suitable for electric or hybrid electric vehicles.

The term “maximum capacity that can be drawn”, as used by the present invention, describes for example the quantity of charge which can be drawn from the cell or the electrical energy store in the fully charged state. In the case of a new cell, the maximum capacity that can be drawn is equal to a rated capacity of the cell. It decreases, however, with progressive ageing. This effect can be described by the so-called “state of health” (SOH).

The term capacity, as used by the present invention, describes a capacity of a cell and generally denotes the quantity of charge which can be stored or output by the cell.

The present invention advantageously makes it possible that a calculation of the life state of the electrical energy store can be performed by means of a measurement of the different characteristic variables such as cell voltage, cell current, maximum state of charge, that is to say maximum possible charging, maximum capacity that can be drawn, battery cell internal resistance, power loss or other operating data.

On the basis of the determined operating data, it is possible to calculate what qualitative state is reached in the sense of a cyclic and/or a calendric lifetime of the electrical energy store.

Said qualitative state is thus calculated depending on running power, non-operation time and age of the electrical energy store taking into consideration the currently prevailing conditions such as a cell temperature or other external influencing factors, for example.

The acquired operating data can be compared with stored characteristic curves or families of characteristic curves, i.e. state of health profiles, and the state of health can be interpreted on the basis of this reference.

On the basis thereof, it is possible to make an assessment of the state of the battery relative to the present battery behavior or use behavior over the entire lifetime.

By virtue of the fact that it is possible to detect if the battery state of the electrical energy store is below predefined reference values, the present invention advantageously makes it possible for various functions in the motor vehicle to be limited or prioritized relative to the power consumption and/or the power output of the electrical energy store.

This advantageously makes it possible to perform a direct influence on functions, such as, for example, the scaling of an electrical drive power or on-board electrical system consumer power.

By way of example, this can advantageously be performed in the case of hybrid functions of the motor vehicle.

In this case, targeted limitations of currents for preventing thermal overloads are activated in order to counteract further increased ageing of the electrical energy store of the motor vehicle.

By way of example, functions for reducing consumption of the electrical energy store of the motor vehicle have the highest priority in the case of a limitation described. This can advantageously be stored in a prioritization table. However, the prioritization can also be represented differently depending on the desired use behavior and depending on the prevailing system architecture.

In the case of large electric machines in hybrid motor vehicles, it is advantageous that the battery supports overtaking procedures and thus enables a maximum driving performance.

The present invention advantageously makes it possible for the control, with a prioritization, a limitation or a deactivation of functions, to dimension the battery or the electrical energy store in accordance with the requirements, such that the desired running power or lifetime of the electrical energy store of the motor vehicle is achieved.

This advantageously makes it possible to save electrical energy.

Furthermore, the present invention advantageously makes it possible that information can be relayed to the driver.

The driver can be notified that increased ageing of the battery is present on account of a personal manner of driving or on account of a treatment of the vehicle in relation to the battery.

Furthermore, advantageously, an approximate running power can be determined statistically and displayed to the driver.

Advantageous configurations of the invention are characterized in the dependent claims.

In one advantageous embodiment of the present invention, it is provided that the acquisition device is designed to acquire, as the operating data of the electrical energy store, data about a module voltage of a cell module or a module temperature or a module current or an internal resistance or a battery voltage of the electrical energy store or a battery current or an internal resistance or a status signal.

In a further advantageous embodiment of the present invention, it is provided that the computer device is designed to process the stored state of health profiles with respect to a cyclic lifetime or a calendric lifetime of the electrical energy store.

In a further advantageous embodiment of the present invention, it is provided that the computer device is designed to compare reference values, present in the stored state of health profiles, about a module voltage of a cell module, a module temperature, a module current, an internal resistance of a cell module, a battery voltage of the electrical energy store, a battery current, an internal resistance of the electrical energy store or a status signal of the electrical energy store, with acquired values.

In a further advantageous embodiment of the present invention, it is provided that the control device is designed to perform the limiting of the power consumption or of the power output of the electrical energy store on the basis of a priority table.

In a further advantageous embodiment of the present invention, it is provided that the control device is designed to perform the limiting of the power consumption or of the power output of the electrical energy store on the basis of a threshold value for a thermal loading of the electrical energy store.

A thermal loading can be provided for example by operation of the electrical energy store outside a predetermined temperature range of −10° C. to +50° C., for example.

In a further advantageous embodiment of the present invention, it is provided that the control device is designed to reduce or to cancel the limiting of the power consumption or of the power output again.

The configurations and developments described can be combined with one another in any desired manner.

Further possible configurations, developments and implementations of the present invention also encompass not explicitly mentioned combinations of features of the invention described above or below with regard to the exemplary embodiments.

### BRIEF DESCRIPTION OF THE FIGURES

The accompanying drawings are intended to convey a further understanding of the embodiments of the present invention.

The accompanying drawings illustrate embodiments and, in association with the description, serve to clarify concepts of the invention.

Other embodiments and many of the advantages mentioned arise in view of the drawings. The illustrated elements of the drawings are not necessarily shown in a manner true to scale with respect to one another.

In the figures:

FIG. 1 shows a schematic illustration of an apparatus for regulating a state of charge of an electrical energy store in accordance with one embodiment of the invention;

FIG. 2 shows a schematic illustration of a flow diagram of a method for regulating a state of charge of an electrical energy store in accordance with a further embodiment of the invention;

FIG. 3 shows a schematic illustration of a block diagram of a method for regulating a state of charge of an electrical energy store in accordance with a further embodiment of the invention; and

FIG. 4 shows a schematic illustration of a diagram of a profile of a state of health and of stored state of health profiles for elucidating the invention.

### DETAILED DESCRIPTION OF EXEMPLARY EMBODIMENTS

In the figures of the drawings, identical reference signs designate identical or functionally identical elements, component parts, components or method steps, unless indicated to the contrary.

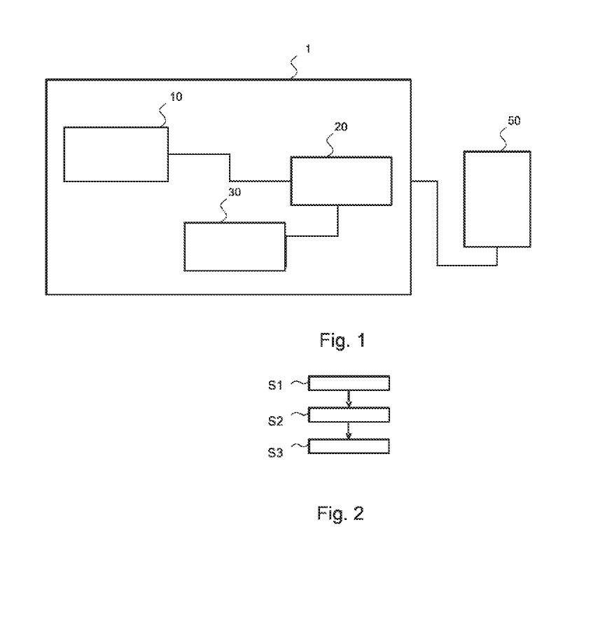

FIG. 1 shows a schematic illustration of an apparatus for regulating a state of charge of an electrical energy store in accordance with one embodiment of the invention.

An apparatus 1 comprises, for example, an acquisition device 10, a computer device 20, and a control device 30.

The acquisition device 10 can be designed, for example, to acquire operating data of the electrical energy store.

The computer device 20 can be designed, for example, to determine a state of health of the electrical energy store with the aid of the acquired operating data and with the aid of stored state of health profiles.

The stored state of health profiles can characterize for example the so-called “state of health” (SOH) of the electrical energy store over a duration of use or a switched-on duration of the electrical energy store 50.

The control device 30 can be designed, for example, to limit a power consumption or a power output of the electrical energy store 50 on the basis of a comparison of the determined state of health of the electrical energy store with a value corridor of the stored state of health profiles.

The apparatus 1 is coupled to an electrical energy store 50, for example.

The apparatus 1 for regulating the state of charge of the electrical energy store 50 can for example be used in a motor vehicle, for instance a hybrid motor vehicle, or be used in a hybrid electric motor vehicle (referred to as hybrid electric vehicle, HEV), i.e. a motor vehicle which is driven by at least one electric motor and a further energy converter.

FIG. 2 shows a schematic illustration of a flow diagram of a method for regulating a state of charge of an electrical energy store in accordance with a further embodiment of the present invention.

A first method step involves, for example, acquiring S1 operating data of the electrical energy store by means of an acquisition device 10.

A second method step involves, for example, determining S2 a state of health of the electrical energy store with the aid of the detected operating data and with the aid of stored state of health profiles by means of a computer device.

A third method step involves, for example, limiting S3 a power consumption and/or a power output of the electrical energy store 50 on the basis of a comparison of the determined state of health of the electrical energy store with a value corridor of the stored state of health profiles by means of a control device 30.

In this case, the method steps can be repeated iteratively or recursively and in an arbitrary order.

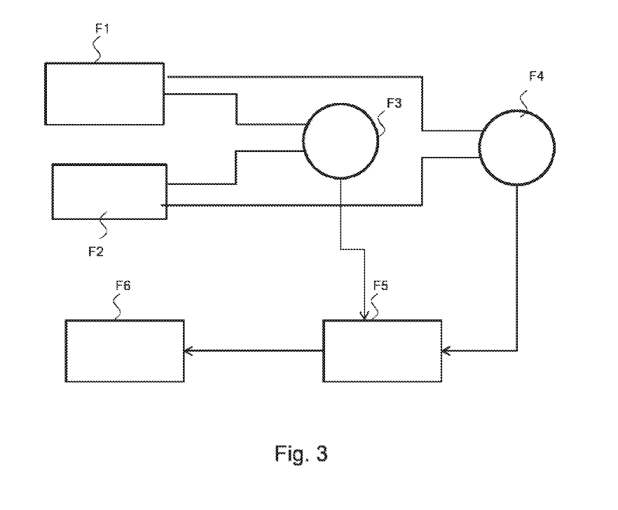

FIG. 3 shows a schematic illustration of a block diagram of a method for regulating a state of charge of an electrical energy store in accordance with a further embodiment of the invention. In a function block F1, for example, an actual value of the state of health, SOH, is determined.

In a function block F2, for example, a setpoint value of the state of health, SOH, is determined.

In function blocks F3 and F4, implemented as operational amplifiers, for example, the actual value of the state of health is compared with the setpoint value of the state of health, for example.

To put it another way, an SOH actual value and an SOH setpoint value are compared by the control device 30. By way of the profile of the ageing of the electrical energy store, it is also possible to compare an SOH setpoint value corridor with an SOH actual value corridor or with an SOH actual value at a current point in time.

By way of example, a limiting intervention can be made by the control device 30, for instance if the SOH actual value falls below the lower SOH setpoint limit of the SOH setpoint value corridor for the current edge t of the electrical energy store.

Furthermore, by way of example, the control device 30 can cancel the limitation again in order to prevent the SOH setpoint corridor from being exceeded by the currently prevailing SOH actual value.

In the function blocks F5 and F6, for example, these involve limiting S3 a power consumption and/or a power output of the electrical energy store 50 on the basis of the determined state of health of the electrical energy store by means of a control device 30.

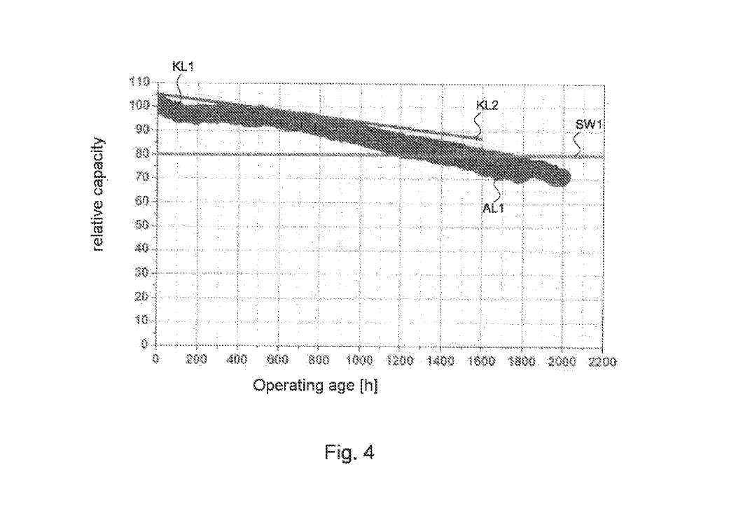

FIG. 4 shows a schematic illustration of a diagram of a profile of a state of health and of stored state of health profiles for elucidating the invention.

FIG. 4 shows a calendric ageing process of an electrical energy store. An SOH threshold value of 80% is represented by the characteristic curve SW1.

A profile of the electrical energy store is characterized for example by its state of health or by its state of health profile KL1.

The state of health profile KL1 lies for example in the value range or value corridor of stored state of health profiles AL1.

To put it another way, the state of health profile KL1 lies within a predetermined or predefinable value corridor of state of health profiles AL1, wherein this is achieved by the limiting or by the cancelling of limitations by the control device 30.

As a result of the regulating strategy of the control device 30 and the interventions made here in the limitation of the power consumption or output, i.e. activation or deactivation of drawing or output maximum loads, for example the upper limit, for instance 105%-85% SOH, for a specific point in time is not exceeded nor is the lower limit, for instance 80% SOH, of the value corridor undershot.

The control device 30 thus regulates for example the compliance with an SOH setpoint corridor by negative intervention, i.e. power limitation, or by a positive intervention, i.e. cancellation of the power limitation, in the output power of the battery or of the electrical energy store.

The state of health profile KL1 comprises for example a variation of the measurement values, which is attributable to a different rate of ageing of identically stored cells of the electrical energy store.

An upper limit or a maximum achievable ageing limit of the state of health profile is given by the characteristic curve KL2.

Although the present invention has been described above on the basis of preferred exemplary embodiments, it is not restricted thereto, but rather is modifiable in diverse ways. In particular, the invention can be altered or modified in diverse ways, without departing from the essence of the invention.

In addition, it should be pointed out that “comprising” and “having” do not preclude other elements or steps and “a(n)” or “one” does not preclude a plurality.

Furthermore, it should be pointed out that features or steps described with reference to one of the above exemplary embodiments can also be used in combination with other features or steps of other exemplary embodiments described above. Reference signs in the claims should not be regarded as restrictions.

What is claimed is:

1. An apparatus for regulating a state of charge of an electrical energy store, the apparatus comprising:
an acquisition device acquiring operating data related to the electrical energy store;
a computer device determining a forecast state of health of the electrical energy store based at least in part on the acquired operating data; and
a control device imposing a limit of power consumption and/or a power output of the electrical energy store, or cancelling such a limit, on the basis of a comparison of the determined forecast state of health of the electrical energy store with a value corridor of stored state of health profiles.

2. The apparatus as claimed in claim 1, wherein the operating data of the electrical energy store include data about a module voltage of a cell module or a module temperature or a module current or an internal resistance or a battery voltage of the electrical energy store or a battery current or an internal resistance or a status signal.

3. The apparatus as claimed in claim 1, wherein the computer device processes the stored state of health profiles with respect to a cyclic lifetime or a calendric lifetime of the electrical energy store.

4. The apparatus as claimed in claim 1, wherein the computer device compares reference values, present in the stored state of health profiles, about a module voltage of a cell module, a module temperature, a module current, an internal resistance of a cell module, a battery voltage of the electrical energy store, a battery current, an internal resistance of the electrical energy store, or a status signal of the electrical energy store, with acquired values.

5. The apparatus as claimed in claim 1, wherein the control device limits of the power consumption or of the power output of the electrical energy store on the basis of a priority table.

6. The apparatus as claimed in claim 1, wherein the control device limits the power consumption or of the power output of the electrical energy store on the basis of a threshold value for a thermal loading of the electrical energy store.

7. The apparatus as claimed in claim 1, wherein the control device cancels the limit of the power consumption or of the power output.

8. A method for regulating a state of charge of an electrical energy store, the method comprising:
acquiring operating data associated with the electrical energy store by means of an acquisition device;
determining a state of health of the electrical energy store based at least in part on the acquired operating data and stored state of health profiles by means of a computer device; and
limiting a power consumption and/or a power output of the electrical energy store on the basis of a comparison of the determined state of health of the electrical energy store with a value corridor of the stored state of health profiles by means of a control device.

9. The method as claimed in claim 8, wherein the operating data includes: a module voltage of a cell module, a module temperature, a module current, an internal resistance of a cell module, a battery voltage of the electrical energy store, a battery current, an internal resistance of the electrical energy store or a status signal of the electrical energy store.

10. The method as claimed in claim 8, the comparison of the determined state of health include comparison of reference values present in the stored state of health profiles, about a module voltage of a cell module, a module temperature, a module current, an internal resistance of a cell module, a battery voltage of the electrical energy store, a battery current, an internal resistance of the electrical energy store or a status signal of the electrical energy store.
